(19) United States
(12) Patent Application Publication
(10) Pub. No.: US 2026/0333995 A1
(43) Pub. Date: Oct. 22, 2026

(54) DISPLAY PANEL AND DISPLAY DEVICE

(71) Applicant: BOE Technology Group Co., Ltd., Beijing (CN)

(72) Inventors: Haiyan SUN, Beijing (CN); Xiaojin ZHANG, Beijing (CN)

(21) Appl. No.: 18/994,116

(22) PCT Filed: Aug. 14, 2024
(86) PCT No.: PCT/CN2024/112124

§ 371 Date: Jan. 14, 2025

(30) Foreign Application Priority Data
Sep. 28, 2023 (CN) 202311285220.9

(51) Int. Cl. H10K 50/12; H10K 50/125; H10K 50/18; H10K 50/19; H10K 101/20; H10K 101/30; H10K 101/40; H10K 102/00

(52) U.S. Cl. CPC H10K 50/121; H10K 50/125; H10K 50/181; H10K 50/19; H10K 2101/20; H10K 2101/30; H10K 2101/40; H10K 2102/351

(57) ABSTRACT

The disclosure relates to a display panel and a display device. The display panel includes a light-emitting structure, and the light-emitting structure includes a first electrode, a first light-emitting unit and a second electrode; the first light-emitting unit is disposed at a side of the first electrode, and the second electrode is disposed at a side of the first light-emitting unit away from the first electrode; the first light-emitting unit includes a first hole transporting layer, a first electron transporting layer, a first light-emitting layer located between the first hole transporting layer and the first electron transporting layer, and a first common electron blocking layer located between the first hole transporting layer and the first light-emitting layer; the first light-emitting layer includes three sub-light-emitting layers, and at least one sub-light-emitting layer includes a material with a TADF characteristic.

### CROSS-REFERENCE TO RELATED APPLICATIONS

The present application is the national phase of International Application No. PCT/CN2024/112124, titled “DISPLAY PANEL AND DISPLAY DEVICE”, filed on Aug. 14, 2024, which claims priority to Chinese Patent Application No. 202311285220.9, titled “DISPLAY PANEL AND DISPLAY DEVICE”, filed on Sep. 28, 2023 with the China National Intellectual Property Administration, which is incorporated herein by reference in its entirety.

### TECHNICAL FIELD

The present application relates to the field of display technologies, and in particular to a display panel and a display device.

### BACKGROUND

An Organic Light-emitting Diode (OLED) display device has a series of advantages such as all-solid-state structure, self-luminescence, fast response speed, high brightness, full viewing angle, flexible display and the like, and thus becomes a type of display device that is currently very competitive and has a good development prospect.

In the OLED display device, a sensitized fluorescence technology is usually used, especially a Thermally Activated Delayed Fluorescence (TADF), which has the advantages of high efficiency and high color purity of fluorescent emitters, and therefore has more technical advantages in the field of display technologies compared with the traditional fluorescence and phosphorescence technologies. However, at present, a structure of a device, to which the TADF is applied, is still relatively complex relative to a common phosphorescent device, and additional evaporation equipment is required, which virtually increases the process difficulty and cost of manufacturing.

### SUMMARY

The present disclosure provides a display panel and a display device to solve the deficiencies in the related art.

In a first aspect according to an embodiment of the present disclosure, a display panel is provided, the display panel includes a light-emitting structure, and the light-emitting structure includes: a first electrode, a first light-emitting unit, and a second electrode; the first light-emitting unit is disposed at a side of the first electrode, and the second electrode is disposed at a side of the first light-emitting unit away from the first electrode; the first light-emitting unit includes a first hole transporting layer, a first electron transporting layer, a first light-emitting layer located between the first hole transporting layer and the first electron transporting layer, and a first common electron blocking layer located between the first hole transporting layer and the first light-emitting layer; and the first light-emitting layer includes three sub-light-emitting layers, and at least one of the three sub-light-emitting layers includes a material having a thermally activated delayed fluorescence characteristic.

Further, the three sub-light-emitting layers are disposed in a spaced-apart manner and disposed between the first common electron blocking layer and the first electron transporting layer; and an area of the first common electron blocking layer is greater than or equal to a sum of areas of the three sub-light-emitting layers.

Further, the first light-emitting layer further includes one or more sub-electron blocking layers, which have the same quantity as one or more sub-light-emitting layers of the three sub-light-emitting layers that do not include the material having the thermally activated delayed fluorescence characteristic.

Further, an area of each of the one or more sub-electron blocking layers is greater than or equal to an area of a corresponding one of the one or more sub-light-emitting layers that do not include the material having the thermally activated delayed fluorescence characteristic; and the one or more sub-electron blocking layers are disposed below the one or more sub-light-emitting layers that do not include the material having the thermally activated delayed fluorescence characteristic in a one-to-one correspondence manner, and are located between the one or more sub-light-emitting layers that do not include the material having the thermally activated delayed fluorescence characteristic and the first common electron blocking layer.

Further, the first light-emitting layer further includes one or more auxiliary light-emitting layers, which have a quantity less than or equal to a quantity of the at least one sub-light-emitting layer including the material having the thermally activated delayed fluorescence characteristic, and an area of each of the one or more auxiliary light-emitting layers is greater than or equal to an area of a corresponding one of the at least one sub-light-emitting layer including the material having the thermally activated delayed fluorescence characteristic; and the one or more auxiliary light-emitting layers are disposed below the at least one sub-light-emitting layer including the material having the thermally activated delayed fluorescence characteristic in a one-to-one correspondence manner, and are located between the at least one sub-light-emitting layer including the material having the thermally activated delayed fluorescence characteristic and the first common electron blocking layer.

Further, a thickness of each of the one or more auxiliary light-emitting layers is less than a thickness of the corresponding one of the at least one sub-light-emitting layer; each of the one or more auxiliary light-emitting layers comprises a light-emitting host material and a material having a thermally activated delayed fluorescence characteristic, which are the same as those of the corresponding one of the at least one sub-light-emitting layer.

Further, the three sub-light-emitting layers comprise a red light-emitting layer, a green light-emitting layer, and a blue light-emitting layer, and the green light-emitting layer comprises the material having the thermally activated delayed fluorescence characteristic; the one or more sub-electron blocking layers comprise a red electron blocking layer and a blue electron blocking layer, the red electron blocking layer and the blue electron blocking layer are disposed below the red light-emitting layer and the blue light-emitting layer, respectively; the one or more auxiliary light-emitting layers comprise a green auxiliary light-emitting layer; the green auxiliary light-emitting layer is disposed below the green light-emitting layer; and an energy level value of a first excited triplet state of the first common electron blocking layer is greater than or equal to an energy level value of a first excited triplet state of the material having the thermally activated delayed fluorescence characteristic included in the green light-emitting layer.

Further, the first common electron blocking layer is made of a hole-type material, which comprises a carbazole-based derivative or an aromatic amine-based derivative, and a thickness of the first common electron blocking layer is less than or equal to 10 nm.

Further, a value of a highest occupied molecular orbital of the blue electron blocking layer is greater than a value of a highest occupied molecular orbital of the blue light-emitting layer, and is less than a value of a highest occupied molecular orbital of the first hole transporting layer; and a value of a first excited singlet state of the blue electron blocking layer is greater than a value of a first excited singlet state of the blue light-emitting layer.

Further, each of an absolute value of a difference between a value of a highest occupied molecular orbital of the first common electron blocking layer and a value of a highest occupied molecular orbital of the first hole transporting layer, an absolute value of a difference between the value of the highest occupied molecular orbital of the first common electron blocking layer and a value of a highest occupied molecular orbital of the blue electron blocking layer, and an absolute value of a difference between the value of the highest occupied molecular orbital of the first common electron blocking layer and a value of a highest occupied molecular orbital of the red electron blocking layer is less than or equal to 0.25 eV.

Further, the light-emitting structure further comprises a first hole blocking layer, and the first hole blocking layer is disposed at a side of the first light-emitting layer away from the first electrode and located between the first light-emitting layer and the first electron transporting layer.

Further, the light-emitting structure further comprises a charge-generation structure and a second light-emitting unit; the charge-generation structure is disposed at a side of the first light-emitting unit away from the first electrode; and the second light-emitting unit is disposed at a side of the charge-generation structure away from the first electrode.

Further, the second light-emitting unit comprises a second hole transporting layer, a second light-emitting layer between the second hole transporting layer and the first electron transporting layer, and a second common electron blocking layer between the second hole transporting layer and the second light-emitting layer; and the second light-emitting layer comprises three sub-light-emitting layers, and at least one of the three sub-light-emitting layers comprises a material having a thermally activated delayed fluorescence characteristic.

Further, the charge-generation structure comprises an N-type charge-generation layer and a P-type charge-generation layer; the N-type charge-generation layer is disposed at a side of the first light-emitting unit away from the first electrode; and the P-type charge-generation layer is disposed at a side of the N-type charge-generation layer away from the first electrode.

Further, the light-emitting structure further comprises a hole injecting layer and an electron injecting layer; the first electrode is an anode, and the second electrode is a cathode; the hole injecting layer is disposed between the first hole transporting layer and the first electrode; and the electron injecting layer is disposed between the first electron transporting layer and the second electrode.

In a second aspect according to an embodiment of the present disclosure, there is provided a display device, including the above display panel.

According to the above embodiments, the present disclosure provides the first common electron blocking layer, there is no need to provide a separate electron blocking layer for the sub-light-emitting layer including the material having the thermally activated delayed fluorescence characteristic, the number of the evaporation chambers and the fine metal masks can be reduced, and the difficulty and cost of the manufacturing process are reduced.

It should be understood that the above general description and the following detailed description are exemplary and explanatory only and are not intended to limit the present disclosure.

### BRIEF DESCRIPTION OF DRAWINGS

The accompanying drawings, which are incorporated in and constitute a part of this specification, illustrate embodiments consistent with the present disclosure and, together with the description, serve to explain the principles of the present disclosure.

FIG. 1 is a schematic diagram of a light-emitting structure according to an embodiment of the present disclosure.

FIG. 2 is a schematic diagram of a second embodiment of the light-emitting structure shown in FIG. 1.

FIG. 3 is a schematic diagram of a third embodiment of the light-emitting structure shown in FIG. 1.

FIG. 4 is a schematic diagram of a plurality of light-emitting units connected in series in the light-emitting structure shown in FIG. 1.

FIG. 5 is a schematic diagram of the light-emitting structure shown in FIG. 4, in which a TADF doping is only performed on a red light-emitting layer.

FIG. 6 is a schematic diagram of the light-emitting structure shown in FIG. 4, in which a TADF doping is performed on both a red light-emitting layer and a green light-emitting layer.

FIG. 7 is a schematic diagram of the light-emitting structure shown in FIG. 4, in which an auxiliary light-emitting layer is added.

FIG. 8 is a schematic diagram of the light-emitting structure shown in FIG. 5, in which an auxiliary light-emitting layer is added.

FIG. 9 is a schematic diagram of the light-emitting structure shown in FIG. 6, in which an auxiliary light-emitting layer is added.

FIG. 10 is a schematic diagram of the light-emitting structure shown in FIG. 4, in which a TADF doping is performed on all sub-light-emitting layers and an auxiliary light-emitting layer is added.

FIG. 11 is a schematic diagram of another embodiment of the light-emitting structure shown in FIG. 4.

Description of reference signs is as follows: 1 first electrode; 2 first light-emitting unit; 21 first hole transporting layer; 22 first common electron blocking layer; 23 first light-emitting layer; 231 sub-light-emitting layer; 2311 red light-emitting layer; 2312 green light-emitting layer; 2313 blue light-emitting layer; 232 sub-electron blocking layer; 2321 red electron blocking layer; 2321a first blocking layer; 2321b second blocking layer; 2322 blue electron blocking layer; 2323 green electron blocking layer; 233 auxiliary light-emitting layer; 2331 green light auxiliary light-emitting layer; 2332 red light auxiliary light-emitting layer; 2333 blue light auxiliary light-emitting layer; 24 first hole blocking layer; 25 first electron transporting layer; 26 hole injecting layer; 27 electron injecting layer; 3 second electrode; 4 encapsulation layer; 5 charge-generation structure; 51 N-type charge-generation layer; 52 P-type charge-generation layer; 6 second light-emitting unit; 61 second hole transporting layer; 62 second common electron blocking layer; 63 second light-emitting layer; 64 second hole blocking layer.

### DETAILED DESCRIPTION

Exemplary embodiments, examples of which are illustrated in the accompanying drawings, will be described in detail herein. When the following description relates to the accompanying drawings, like numerals indicate like or similar elements unless otherwise indicated. The embodiments described in the following exemplary embodiments do not represent all embodiments consistent with the present disclosure. Rather, they are merely examples of devices and methods consistent with some aspects of the present disclosure as detailed in the appended claims.

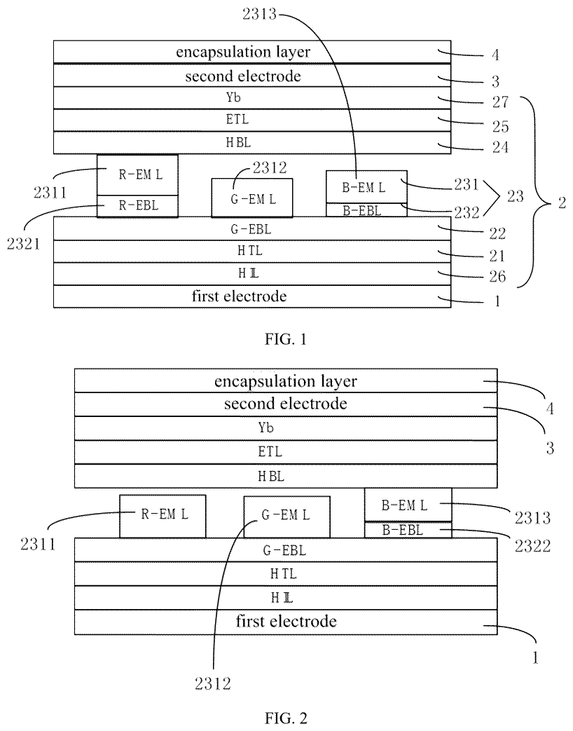

Referring to FIG. 1, the present disclosure provides a display panel. The display panel includes a light-emitting structure, which includes a first electrode 1, a first light-emitting unit 2, and a second electrode 3. The first light-emitting unit 2 is disposed at a side of the first electrode 1, and the second electrode 3 is disposed at a side of the first light-emitting unit 2 away from the first electrode 1.

The first electrode 1 may be a cathode or an anode. When the first electrode 1 is the anode, the second electrode 3 is the cathode; on the contrary, when the first electrode 1 is the cathode, the second electrode 3 is the anode.

In an embodiment of the present disclosure, preferably, the first electrode 1 is the anode.

The first electrode 1 is made of an electrode material having a high work function, which may be a transparent oxide such as indium tin oxide (ITO) or tin zinc oxide (IZO), and when the above electrode material is used, a thickness of the first electrode 1 may optionally be greater than 80 nm and less than 200 nm. In this case, the display panel provided by the present disclosure has a bottom-emission structure.

The first electrode 1 may also be a composite electrode formed from metals and oxides, such as Ag/ITO, Al/ITO, Ag/ITO, Al/IZO, or the like. At this time, a thickness of a metal layer in the composite electrode should be greater than 10 nm and less than 100 nm, and a thickness of a corresponding oxide layer should be greater than 5 nm and less than 20 nm. In this case, the display panel provided by the present disclosure has a top-emission structure.

The second electrode 3 is thus the cathode, which may be made of a metal material having a lower work function, such as Al, Ag, Mg, or the like, or may be made of an alloy containing a metal material with a lower work function. When the display panel has the bottom-emission structure, a thickness of the second electrode 3 is greater than 80 nm to ensure that the second electrode 3 has good reflectivity. Preferably, the reflectivity of the second electrode 3 for light with a wavelength of 550 nm should be greater than 85%.

When the display panel has the top-emission structure, the thickness of the second electrode 3 should be adjusted to be greater than 10 nm and less than 20 nm to ensure the transmittance thereof. Preferably, in this case, the transmittance of the second electrode 3 for the light with the wavelength of 550 nm should be greater than 45%, and the metal layer of the second electrode 3 should be covered with an optical capping layer (Capping Layer, CPL), thereby improving the optical output thereof. Preferably, the optical capping layer is made of a small molecular material having a higher refractive index by evaporation. Further, the refractive index of the optical capping layer should be greater than 1.8 at 550 nm, and a thickness of the optical capping layer should be greater than 50 nm, and less than 100 nm.

As shown in FIG. 1, an encapsulation layer 4 is disposed on the second electrode 3, and the first electrode 1, the second electrode 3 and the first light-emitting unit 2 are wrapped inside to prevent the external environment from causing damage to them. The encapsulation layer 4 may be encapsulated by a UV sealant or a thin film encapsulation (TFE).

The first light-emitting unit 2 includes a hole injecting layer 26, a first hole transporting layer 21, a first light-emitting layer 23, a first hole blocking layer 24, a first electron transporting layer 25, and an electron injecting layer 27 that are stacked sequentially from bottom to top.

The first light-emitting layer 23 includes three sub-light-emitting layers 231, which are respectively a red light-emitting layer 2311, a green light-emitting layer 2312 and a blue light-emitting layer 2313, and at least one of the three sub-light-emitting layers 231 includes a material having a thermally activated delayed fluorescence characteristic. A first common electron blocking layer 22 is further disposed between the first hole transporting layer 21 and the first light-emitting layer 23.

The three sub-light-emitting layers 231 are arranged in a spaced-apart manner and disposed between the first common electron blocking layer 22 and the first electron transporting layer 25, and the area of the first common electron blocking layer 22 is greater than or equal to the sum of the areas of the three sub-light-emitting layers 231. The first light-emitting layer 23 further includes a pixel defining layer (not shown), the pixel defining layer is disposed between the three sub-light-emitting layers 231, and the three sub-light-emitting layers 231 are separated by the pixel defining layer. Due to the limitations of the process, in an embodiment, edge regions of the three sub-light-emitting layers 231 may partially overlap each other, in particular, the red light-emitting layer 2311 may partially overlap with an adjacent green light-emitting layer 2312 or an adjacent blue light-emitting layer 2313 in the edge region.

An electron blocking layer (EBL) is a layered material applied in semiconductor devices. The electron blocking layer has the main function of blocking unnecessary transport or leakage of electrons in the device, effectively preventing electrons from entering a region of a irrelevant layer from the electron transporting layer or the electrode, ensuring the accuracy and stability of electron injecting, and helping to improve the electron transporting efficiency and the light-emitting effect of the device; the electron blocking layer has a certain energy band barrier, so that the leakage current in the device can be effectively reduced or blocked; the electron blocking layer can also be used for optimizing interface matching between different materials, the energy level gap between the material interfaces can be filled, the transport efficiency of electrons among different materials is improved, and the non-ideal phenomena of energy band bending, reflection and the like are reduced.

Therefore, in the conventional solution, a corresponding electron blocking layer is generally disposed beneath each of the sub-light-emitting layers 231, an area of the electron blocking layer should be greater than or equal to an area of the corresponding sub-light-emitting layer 231, a thickness of a red electron blocking layer is greater than a thickness of a blue electron blocking layer, and a thickness of the blue electron blocking layer is greater than a thickness of a green electron blocking layer. However, the conventional electron blocking layer is formed by an evaporation process using a fine metal mask, and the manufacturing process is difficult and costly.

On the basis of the conventional solution, the present disclosure further provides the first common electron blocking layer 22, the three sub-light-emitting layers 231 are all located between the first common electron blocking layer 22 and the first electron transporting layer 25, there is no need to separately provide the electron blocking layer for the sub-light-emitting layer 231 including the material with the thermally activated delayed fluorescence characteristic, so that the number of electron blocking layers can be accordingly reduced, thereby reducing the number of evaporation chambers and fine metal masks, and reducing the difficulty and cost of the manufacturing process.

Referring to FIG. 1 to FIG. 3, the at least one sub-light-emitting layer 231 mentioned in the present disclosure includes the material with the thermally activated delayed fluorescence characteristic, meaning that one sub-light-emitting layer 231 may be doped with the thermally activated delayed fluorescence material, or two or even all of the sub-light-emitting layers 231 may be doped with the thermally activated delayed fluorescence material.

When only one sub-light-emitting layer 231 is doped with the thermally activated delayed fluorescence material, for example, referring to FIG. 1, the green light-emitting layer 2312 is doped with the thermally activated delayed fluorescence material, the green light-emitting layer 2312 does not need to be provided with its corresponding separate electron blocking layer, and the electron blocking effect can be achieved only by the first common electron blocking layer 22. In this case, the red light-emitting layer 2311 and the blue light-emitting layer 2313 are provided with a red electron blocking layer 2321 and a blue electron blocking layer 2322 disposed therebelow, respectively. Since both the red light-emitting layer 2311 and the blue light-emitting layer 2313 are located above the first common electron blocking layer 22, the first common electron blocking layer 22 can further enhance the effects of the red electron blocking layer 2321 and the blue electron blocking layer 2322.

The present embodiment is not limited to only performing the thermally activated delayed fluorescence doping on the green light-emitting layer 2312, the red light-emitting layer 2311 and the blue light-emitting layer 2313 may also be used as embodiments, and details are not described herein again.

When thermally activated delayed fluorescence doping is performed on the two sub-light-emitting layers 231, for example, referring to FIG. 2, the red light-emitting layer 2311 and the green light-emitting layer 2312 are doped with the thermally activated delayed fluorescence material, there is no need to provide corresponding separate electron blocking layers for the red light-emitting layer 2311 and the green light-emitting layer 2312 respectively, and the electron blocking effect can be achieved only by the first common electron blocking layer 22. At this time, a corresponding blue electron blocking layer 2322 is disposed beneath the blue light-emitting layer 2313.

The two sub-light-emitting layers 231 on which the thermally activated delayed fluorescence doping are performed are not limited to the red light-emitting layer 2311 and the green light-emitting layer 2312, and it can be anticipated that the red light-emitting layer 2311 and the blue light-emitting layer 2313, the green light-emitting layer 2312 and the blue light-emitting layer 2313 may also be used in other embodiments, and details are not described herein again.

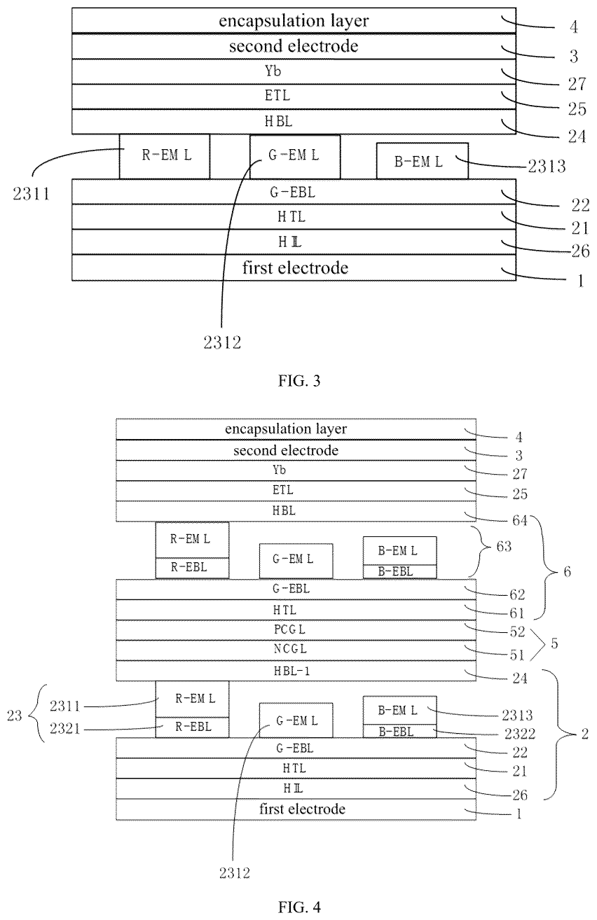

When thermally activated delayed fluorescence doping is performed on the three sub-light-emitting layers 231, referring to FIG. 3, the electron blocking effect can be achieved for all the sub-light-emitting layers 231 only by the first common electron blocking layer 22.

Specifically, with reference to FIG. 1, which shows an example in which the thermally activated delayed fluorescence doping is performed as an example on the single green light-emitting layer 2312, in this embodiment, the hole injecting layer 26 may be made of an injection material such as CuPc or HATCN or MnO3, or may be formed by performing p-type doping on the hole transporting material. When performing p-type doping on the hole transporting material is applied, optionally, the p-type dopant may be an oxide-based inorganic material or radialene-based organic material. The thickness of the hole injecting layer 26 should be greater than 1 nm, and less than 30 nm. The hole injecting layer 26 may be formed by a multi-source co-evaporation process.

The first hole transporting layer 21 may be formed of a material having good hole transporting characteristic, including a carbazole and a derivative thereof which have a higher hole mobility. The thickness of the first hole transporting layer 21 should be greater than 1 nm and less than 200 nm.

The electron injecting layer 27 may be formed of a low work function metal material such as Li, Ca, Yb or metal salt such as LiF or LiQ3 by the evaporation process. The thickness of the electron injecting layer 27 should be greater than 0.5 nm and less than 2 nm. In an embodiment of the present disclosure, the electron injecting layer 27 is formed of the metal material Yb by the evaporation process.

The first common electron blocking layer 22 has a high first excitation triplet energy level, which is at least not lower than a first excitation triplet energy level of the thermally activated delayed fluorescent material in the green light-emitting layer 2312, and the first common electron blocking layer 22 is configured to block the leakage of excitons in the light-emitting layer, thereby improving efficiency and stability. The first common electron blocking layer 22 may include a material selected from hole-type materials such as carbazole-based derivatives, aromatic amine-based derivatives, and has a thickness of not more than 10 nm.

The blue electron blocking layer 2322 is used to reduce the transport barrier of holes from the adjacent first hole transporting layer 21 to the blue light-emitting layer 2313, and hence the highest occupied molecular orbital energy level value of the material in this layer should be numerically between the highest occupied molecular orbital energy level of the adjacent first hole transporting layer 21 and the highest occupied molecular orbital energy level of the host material of the blue light-emitting layer 2313. Meanwhile, the blue electron blocking layer 2322 further has an exciton-block effect, and should ensure that energy of the first excited singlet state of the material in this layer is greater than that of the first excited singlet state of the material in the blue light-emitting layer 2313. Alternatively, the material of this layer may be carbazole and its derivatives.

The red electron blocking layer 2321 is used for reducing the transport barrier of holes from the adjacent first hole transporting layer 21 to the red light-emitting layer 2311, while ensuring that excitons in the light-emitting layer do not overflow. Alternatively, the material of this layer may be carbazole and its derivatives.

The blue light-emitting layer 2313 includes at least a host material and a fluorescent guest material. The emission spectrum of the host material has a large overlap with the absorption spectrum of the guest material, and under the normalized spectral condition, the area of the overlap region of the host material accounts for no less than 60% of the area of the absorption spectrum of the guest material. The host material optionally includes anthracene, fluorene, pyrene, or their derivatives. The guest material may be pyrene-based organic material, or may be boron-containing organic material, a doping concentration may be adjusted in a range from 0.5% to 5%, and its main emission peak wavelength should be greater than 450 nm and less than 480 nm.

The green light-emitting layer 2312 includes a hole-type host material, a material having a thermally activated delayed fluorescence characteristic, and a fluorescent guest material. The hole-type host material may be a carbazole-based material, the material with the thermally activated delayed fluorescence characteristic may be a multi-carbazole-based material having a D-L-A structure, and the fluorescent guest material may be a boron-containing organic material. An energy level of a first excited triplet state of the host material is higher than an energy level of a first excited triplet state of the material with the thermally activated delayed fluorescence characteristic. Preferably, the energy level of the first excited triplet state of the hole-type host material is at least 0.1 eV higher than that of the material with the thermally activated delayed fluorescence characteristic. The emission spectrum of the material with the thermally activated delayed fluorescence characteristic has a large overlap with the absorption spectrum range of the guest material, and optimally, the area of the overlap region of the normalized spectrum of the material with the thermally activated delayed fluorescence characteristic needs to account for more than 60% of the area of the absorption spectrum of the guest material.

The red light-emitting layer 2311 includes at least a P-type host material, an N-type host material, and a light-emitting guest material. The N-type host material may be a common material or a material with the thermally activated delayed fluorescence characteristic. The light-emitting guest material may be a phosphorescent material or a boron-containing fluorescent material. The thickness of the red light-emitting layer 2311 may be adjusted in a range of greater than 30 nm and less than 80 nm.

The thickness of the first hole blocking layer 24 should be greater than 5 nm and less than 30 nm, an energy level of a first excited triplet state of the material in this layer needs to be greater than an energy level of a first excited triplet state of the material with the thermally activated delayed fluorescence characteristic in the green light-emitting layer 2312 connected to the first hole blocking layer 24, preferably, the difference thereof should be greater than or equal to 0.2 eV. The absolute value of the highest occupied molecular orbital energy level of the material in the first hole blocking layer 24 needs to be greater than the absolute value of the highest occupied molecular orbital energy level of all the sub-light-emitting layers 231 connected to the first hole blocking layer 24, preferably, the difference should be greater than 0.2 eV. The absolute value of the lowest unoccupied molecular orbital energy level of the material in the first hole blocking layer 24 needs to be less than the absolute value of the lowest unoccupied molecular orbital energy level of the material in all the sub-light-emitting layers 231 connected to the first hole blocking layer 24.

The electron injecting layer 27 may be formed of a material having good electron transporting characteristics by the evaporation process, or may be formed by doping LIQ3 with materials such as Li and Ca in a certain ratio in the electron transporting material. The absolute value of the lowest unoccupied molecular orbital energy level of all materials in the electron injecting layer 27 needs to be greater than the absolute value of the lowest unoccupied molecular orbital energy level of the material of the first hole blocking layer 24 connected to the electron injecting layer 27.

It should be noted that the energy levels and the mobility of the first common electron blocking layer 22 and the adjacent film layer should satisfy the following relationship:
   |HOMO (G EBL)−HOMO (HTL)|≤0.25 eV, preferably, ≤0.15 eV
   |HOMO (G EBL)−HOMO (B EBL)|≤0.25 eV, preferably, ≤0.15 eV
   |HOMO (G EBL)−HOMO (R EBL)|≤0.25 eV

The HOMO (G EBL) refers to the value of the HOMO energy level of the first common electron blocking layer 22, the HOMO (HTL) refers to the value of the HOMO energy level of the first hole transporting layer 21 (HTL, Hole Transporting Layer), the HOMO (B EBL) refers to the value of the HOMO energy level of the blue electron blocking layer 2322, and the HOMO (R EBL) refers to the value of the HOMO energy level of the red electron blocking layer 2321.

In this case, it is ensured that the holes can be smoothly injected into the red light-emitting layer 2311 and the blue light-emitting layer 2313;

Preferably, since a turn-on voltage of the red light-emitting layer 2311 is lower than that of the blue light-emitting layer 2313, the potential barrier of the red light-emitting layer 2311 should be increased, the turn-on voltage of the red light-emitting layer 2311 should be increased, and the voltage difference between the red light-emitting layer 2311 and the blue light-emitting layer 2313 should be reduced, so as to facilitate better display of the image. Therefore, it is necessary to satisfy: |HOMO (G EBL)−HOMO (R EBL)|≥|HOMO (G EBL)−HOMO (B EBL)|.

Preferably, since the turn-on voltage of the red light-emitting layer 2311 is lower than that of the blue light-emitting layer 2313, due to the presence of the first common electron blocking layer 22, the hole mobility is subject to the following conditions to prevent the crosstalk problem caused by lateral leakage:
10⁻⁵<hole mobility (G EBL)/hole mobility (HTL)<10⁻³
10⁻⁴<hole mobility (G EBL)/hole mobility (R EBL)<10⁻²
10⁻²<hole mobility (G EBL)/hole mobility (B EBL)<10
10⁻³<hole mobility (B EBL)/hole mobility (R EBL)<10⁻¹.

The hole mobility (G EBL) refers to the hole mobility of the first common electron blocking layer 22, the hole mobility (HTL) refers to the hole mobility of the first hole transporting layer 21 (HTL, Hole Transporting Layer), the hole mobility (B EBL) refers to the hole mobility of the blue electron blocking layer 2322, and the hole mobility (R EBL) refers to the hole mobility of the red electron blocking layer 2321.

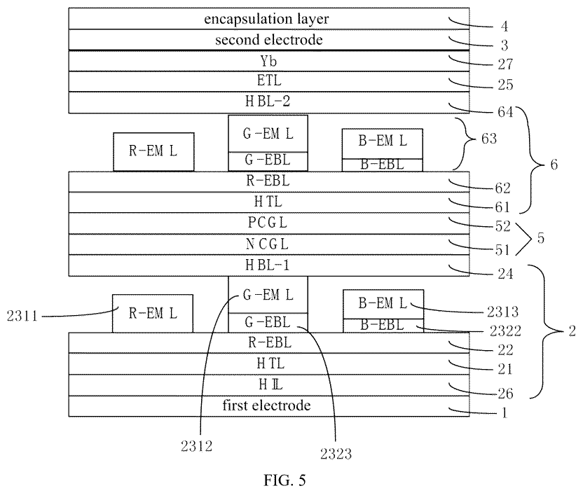

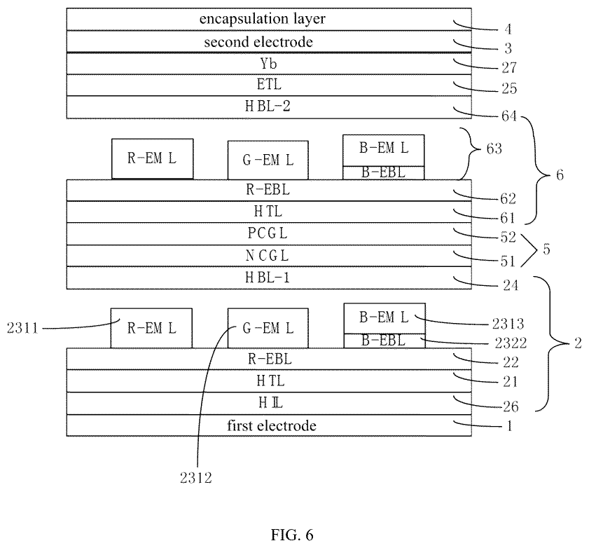

The light-emitting structure in the above-mentioned embodiment includes only one light-emitting unit. In another embodiment, referring to FIGS. 4 to 11, the light-emitting structure of the present disclosure further includes a charge-generation structure 5 and a second light-emitting unit 6. The charge-generation structure 5 is disposed at a side of the first light-emitting unit 2 away from the first electrode 1, and the second light-emitting unit 6 is disposed at a side of the charge-generation structure 5 away from the first electrode 1.

In this embodiment, two light-emitting units are connected in series through a charge-generation structure 5 therebetween to form a light-emitting structure, or three or more light-emitting units may be connected in series through charge-generation structures 5 therebetween to form a light-emitting structure, which is not limited in this embodiment.

The second light-emitting unit 6 includes a second hole transporting layer 61, a second light-emitting layer 63 between the second hole transporting layer 61 and the first electron transporting layer 25, and a second common electron blocking layer 62 between the second hole transporting layer 61 and the second light-emitting layer 63. The second light-emitting layer 63 includes three sub-light-emitting layers 231, and the at least one sub-light-emitting layer 231 includes a material having a thermally activated delayed fluorescence property.

The charge-generation structure 5 includes an N-type charge-generation layer 51 and a P-type charge-generation layer 52. The N-type charge-generation layer 51 is disposed at a side of the first light-emitting unit 2 away from the first electrode 1, and the P-type charge-generation layer 52 is disposed at a side of the N-type charge-generation layer 51 away from the first electrode 1.

The N-type charge-generation layer 51 may be formed of an electron transporting type material doped with a low work function active metal, such as Li or Ca or Yb.

The P-type charge-generation layer 52 may be formed of a hole-transporting type material doped with a P-type dopant such as molybdenum oxide, etc. The proportion of the doped P-type dopants in the P-type charge-generation layer 52 needs to be higher than a doping proportion in the hole injecting layer 26, thereby facilitating charge generation.

In this embodiment, the structure of the second light-emitting unit 6 is the same as the structure of the first light-emitting unit 2, and materials of various film layers for forming the second light-emitting unit 6 may be same as the materials of the first light-emitting unit 2, or may be different from the materials of the first light-emitting unit 2.

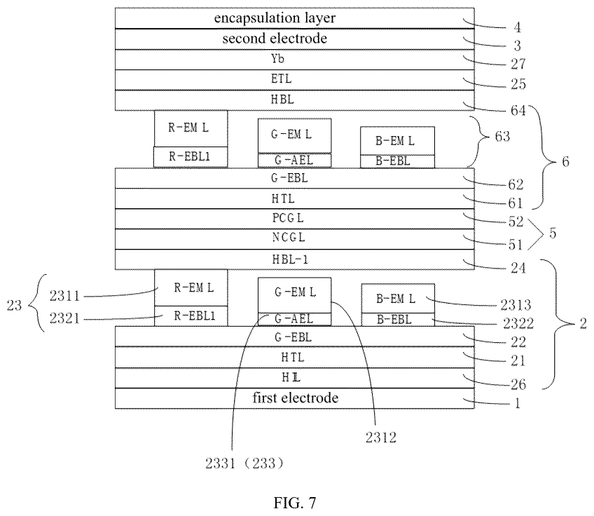

Referring to FIGS. 7 to 10, the first light-emitting layer 23 further includes an auxiliary light-emitting layer 233. The auxiliary light-emitting layer 233 is disposed between the sub-light-emitting layer 231 doped with the material having the thermally activated delayed fluorescence characteristic and the first common electron blocking layer 22. In an embodiment shown in FIG. 7, a green auxiliary light-emitting layer 2331 is disposed beneath the green light-emitting layer 2312.

A thickness of the green auxiliary light-emitting layer 2331 is less than a thickness of the green light-emitting layer 2312. The green auxiliary light-emitting layer 2331 includes a light-emitting host material and a material having a thermally activated delayed fluorescence characteristic, and the light-emitting host material and the material having the thermally activated delayed fluorescence characteristic are the same as a light-emitting host material and a material having a thermally activated delayed fluorescence characteristic of the green light-emitting layer 2312.

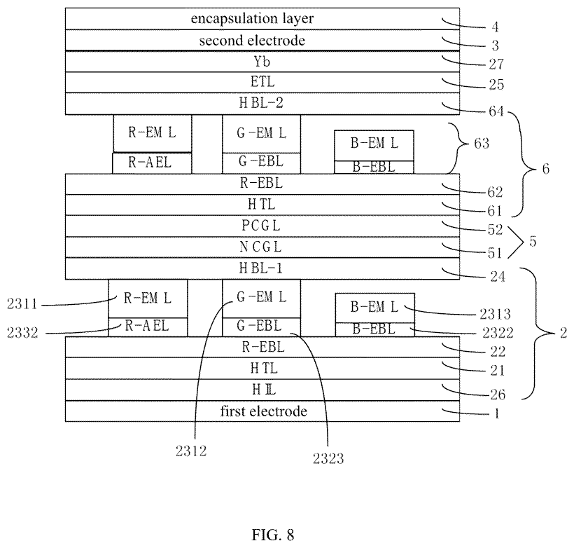

As shown in FIG. 8, in this embodiment, a thermally activated delayed fluorescence doping is performed on a red light-emitting layer 2311, and hence a red auxiliary light-emitting layer 2332 is disposed beneath the red light-emitting layer 2311.

A thickness of the red auxiliary light-emitting layer 2332 is less than a thickness of the red light-emitting layer 2311. The red auxiliary light-emitting layer 2332 includes a light-emitting host material and a material having a thermally activated delayed fluorescence characteristic, and the light-emitting host material and the material having the thermally activated delayed fluorescence characteristic are the same as a light-emitting host material and a material having a thermally activated delayed fluorescence characteristic of the red light-emitting layer 2311.

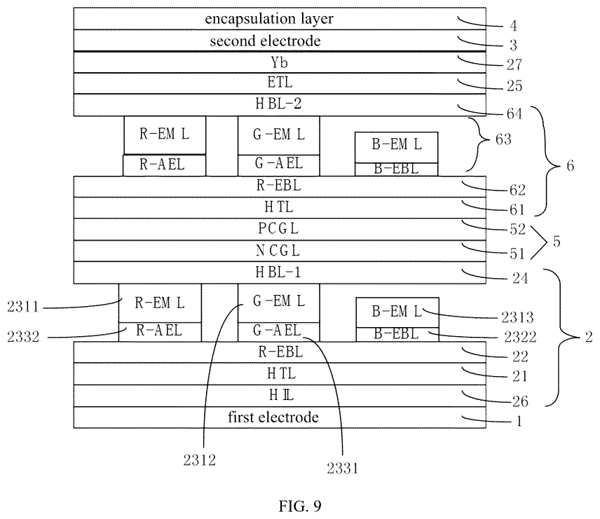

As shown in FIG. 9, in this embodiment, a thermally activated delayed fluorescence doping is performed on both a red light-emitting layer 2311 and a green light-emitting layer 2312, and hence a red auxiliary light-emitting layer 2332 and a green auxiliary light-emitting layer 2331 are correspondingly disposed beneath the red light-emitting layer 2311 and the green light-emitting layer 2312, respectively.

Properties of the red auxiliary light-emitting layer 2332 and the green light auxiliary light-emitting layer 2331 have been described above in the embodiment of FIG. 8, and details are not described herein again.

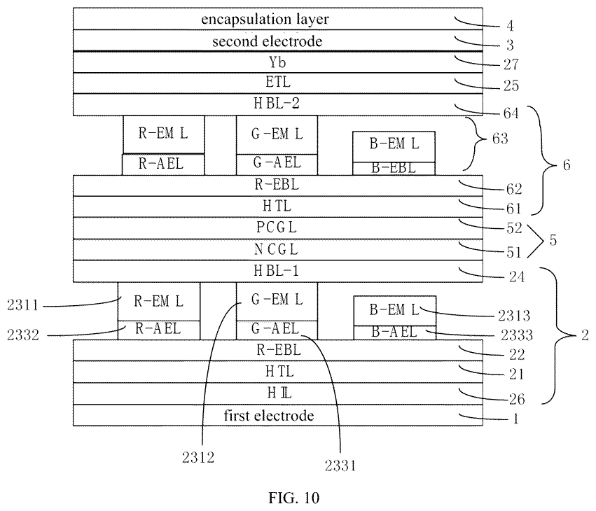

As shown in FIG. 10, in this embodiment, a thermally activated delayed fluorescence doping is performed on all sub-light-emitting layers 231, and hence auxiliary light-emitting layers 233 are correspondingly disposed beneath all the sub-light-emitting layers 231. In this embodiment, the auxiliary light-emitting layers 233 include a green auxiliary light-emitting layer 2331, a red auxiliary light-emitting layer 2332, and a blue auxiliary light-emitting layer 2333.

The red auxiliary light-emitting layer 2332 and the green auxiliary light-emitting layer 2331 have been described in the foregoing embodiments, and details are not described herein again. For the blue auxiliary light-emitting layer 2333, a thickness of the blue auxiliary light-emitting layer 2333 is less than a thickness of the blue light-emitting layer 2313. The blue auxiliary light-emitting layer 2333 includes a light-emitting host material and a material having a thermally activated delayed fluorescence characteristic, and the light-emitting host material and the material having the thermally activated delayed fluorescence characteristic are the same as a light-emitting host material and a material having a thermally activated delayed fluorescence characteristic of the blue light-emitting layer 2313.

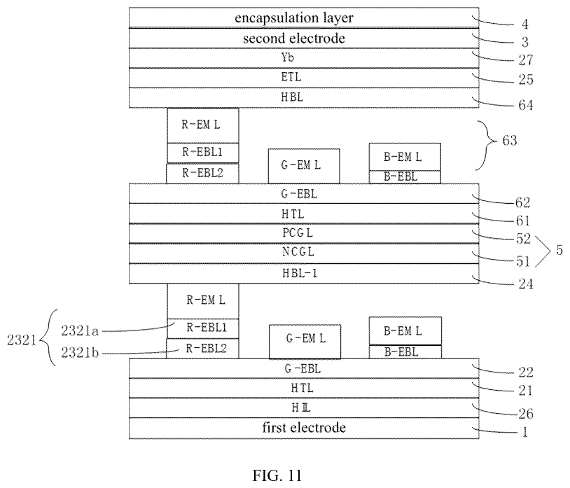

Referring to FIG. 11, in this embodiment, a red electron blocking layer 2321 includes a first blocking layer 2321a and a second blocking layer 2321b. The first blocking layer 2321a and the second blocking layer 2321b are stacked to form the red electron blocking layer 2321, so that a voltage of the red light-emitting layer 2311 is effectively increased, a voltage difference between the red light-emitting layer 2311 and the blue light-emitting layer 2313 is reduced, the crosstalk problem is improved, the device efficiency of the red light-emitting layer 2311 is improved, and the power consumption of the whole device can be reduced.

Specific structures and characteristics of resulted devices in the embodiments of the present disclosure are as follows:

TABLE 1

| | | Current | | | Color | |
|---|---|---|---|---|---|---|
| | Device | Density | Voltage | Efficiency | Coordinates | LT95 |
| Item | ID | (mA/cm2) | (V) | (cd/A) | (CIE-1931) | Lifespan |
| Example 1 | R | 15 | 6.8 | 100% | 0.685, 0.315 | 100% |
| | G | 15 | 7.1 | 100% | 0.197, 0.754 | 100% |
| | B | 15 | 7.2 | 100% | 0.141, 0.042 | 100% |
| Example 2 | R | 15 | 6.9 | 100% | 0.685, 0.315 | 100% |
| | G | 15 | 7.1 | 98% | 0.197, 0.754 | 102% |
| | B | 15 | 7.4 | 103% | 0.141, 0.042 | 100% |
| Example 3 | R | 15 | 7.0 | 100% | 0.685, 0.315 | 100% |
| | G | 15 | 7.1 | 100% | 0.197, 0.754 | 112% |
| | B | 15 | 7.4 | 103% | 0.141, 0.042 | 100% |
| Example 4 | R | 15 | 6.9 | 101% | 0.685, 0.315 | 98% |
| | G | 15 | 7.0 | 103% | 0.197, 0.754 | 108% |
| | B | 15 | 7.4 | 103% | 0.141, 0.042 | 100% |
| Example 5 | R | 15 | 6.9 | 103% | 0.685, 0.315 | 98% |
| | G | 15 | 7.1 | 101% | 0.197, 0.754 | 109% |
| | B | 15 | 7.4 | 103% | 0.141, 0.042 | 100% |
| Example 6 | R | 15 | 7.3 | 102% | 0.685, 0.315 | 103% |
| | G | 15 | 7.1 | 99% | 0.197, 0.754 | 102% |
| | B | 15 | 7.4 | 103% | 0.141, 0.042 | 100% |

### Example 1

A device including following layers from bottom to top was provided:
a first electrode 1: metal Ag (thickness of 100 nm)/ITO layer (thickness of 8 nm);
a first hole injecting layer 26/a first hole transporting layer 21: hole transporting (HT): p-type dopant (thickness of 10 nm, doping concentration of 3%)/hole transporting (HT) (B color adjustment);
a first light-emitting layer 23: a red electron blocking layer 2321/a red light-emitting layer 2311: red host (RH)+a red dopant (RD) (doping concentration of 3%); a green electron blocking layer 2323/a green light-emitting layer 2312: a green host (GH)+G-TADF+a green dopant (GD) (a ratio of 69%: 30%: 1.0%); a blue electron blocking layer 2322 (thickness of 5 nm)/a blue light-emitting layer 2313: a blue host (BH)+a blue dopant (BD) (doping concentration of 3%);
a first hole blocking layer 24: HB (5 nm);
a charge-generation structure 5: N-type charge-generation layer 51: n-CG: Yb (1%)/P-type charge-generation layer 52: HT: p-type dopant (thickness of 10 nm, doping concentration of 10%);
a second hole transporting layer 61;
a second light-emitting layer 63: a red electron blocking layer 2321/a red light-emitting layer 2311: a red host (RH)+a red dopant (RD) (doping concentration of 3%); a green electron blocking layer 2323/a green light-emitting layer 2312: a green host (GH)+G-TADF+a green dopant (GD) (a ratio of 69%: 30%: 1.0%); a blue electron blocking layer 2322 (thickness of 5 nm)/a blue light-emitting layer 2313: a blue host (BH)+a blue dopant (BD) (doping concentration of 3%);
a second hole blocking layer 64: hole blocking (HB) (thickness of 5 nm);
a first electron transporting layer 25: LiQ (liquid Li) (thickness of 35 nm, a ratio of liquid Li to liquid lead is 50%: 50%);
an electron injecting layer 27: an electron injecting layer (EIL) (thickness of 1 nm);
a second electrode 3: Mg and Ag alloy (thickness of 15 nm)+an optical capping layer CPL (capping layer).

In this example 1, a corresponding electron blocking layer was disposed beneath each of the sub-light-emitting layers 231, which is used as a comparative example.

### Example 2

A first electrode 1: metal Ag (thickness of 100 nm)/ITO layer (thickness of 8 nm);

A first hole injecting layer 26/a first hole transporting layer 21: hole transporting (HT): p-type dopant (thickness of 10 nm, doping concentration of 3%)/hole transporting (HT) (B color adjustment);

A first common electron blocking layer 22 (thickness of 5 nm);

A first light-emitting layer 23: a red electron blocking layer 2321/a red light-emitting layer 2311: a red host (RH)+a red dopant (RD) (doping concentration of 3%); a green light-emitting layer 2312: a green host (GH)+G-TADF+a green dopant (GD) (a ratio of 69%: 30%: 1.0%); a blue electron blocking layer 2322 (thickness of 5 nm)/a blue light-emitting layer 2313: a blue host (BH)+a blue dopant (BD) (doping concentration of 3%);

A first hole blocking layer 24: HB (5 nm);

A charge-generation structure 5: N-type charge-generation layer 51: n-CG: Yb (1%)/P-type charge-generation layer 52: HT: p-type dopant (thickness of 10 nm, doping concentration of 10%);

A second hole transporting layer 61;

A second common electron blocking layer 62 (thickness of 5 nm);

A second light-emitting layer 63: a red electron blocking layer 2321/a red light-emitting layer 2311: a red host (RH)+a red dopant (RD) (doping concentration of 3%); a green light-emitting layer 2312: a green host (GH)+G-TADF+a green dopant (GD) (a ratio of 69%: 30%: 1.0%); a blue electron blocking layer 2322 (thickness of 5 nm)/a blue light-emitting layer 2313: a blue host (BH)+a blue dopant (BD) (doping concentration of 3%);

A second hole blocking layer 64: hole blocking (HB) (thickness of 5 nm);

A first electron transporting layer 25: LiQ (liquid Li) (thickness of 35 nm, a ratio of liquid Li to liquid lead is 50%: 50%);

An electron injecting layer 27: an electron injecting layer (EIL) (thickness of 1 nm);

A second electrode 3: Mg and Ag alloy (thickness of 15 nm)+an optical capping layer CPL (capping layer).

Referring to Table 1 and FIG. 4, the first common electron blocking layer 22 was added in this example, device performance of this example was substantially equivalent to that of Example 1, but compared with Example 1, one chamber and a fine metal masks were omitted in Example 2, thereby effectively reducing the process flow and the cost.

### Example 3

A first electrode 1: metal Ag (thickness of 100 nm)/ITO layer (thickness of 8 nm);

A first hole injecting layer 26/a first hole transporting layer 21: hole transporting (HT): p-type dopant (thickness of 10 nm, doping concentration of 3%)/hole transporting (HT) (B color adjustment);

A first common electron blocking layer 22 (thickness of 5 nm);

A first light-emitting layer 23: a red electron blocking layer 2321/a red light-emitting layer 2311: a red host (RH)+a red dopant (RD) (doping concentration of 3%); a green auxiliary light-emitting layer 2331: a green host (GH)+G-TADF (a ratio of 70%: 30%)/a green light-emitting layer 2312: a green host (GH)+G-TADF+a green dopant (GD) (a ratio of 69%: 30%: 1.0%); a blue electron blocking layer 2322 (thickness of 5 nm)/a blue light-emitting layer 2313: a blue host (BH)+a blue dopant (BD) (doping concentration of 3%);

A first hole blocking layer 24: HB (5 nm);

A charge-generation structure 5: N-type charge-generation layer 51: n-CG: Yb (1%)/P-type charge-generation layer 52: HT: p-type dopant (thickness of 10 nm, doping concentration of 10%);

A second hole transporting layer 61;

A second common electron blocking layer 62 (thickness of 5 nm);

A second light-emitting layer 63: a red electron blocking layer 2321/a red light-emitting layer 2311: a red host (RH)+a red dopant (RD) (doping concentration of 3%); a green auxiliary light-emitting layer 2331: a green host (GH)+G-TADF (a ratio of 70%: 30%)/a green light-emitting layer 2312: a green host (GH)+G-TADF+a green dopant (GD) (a ratio of 69%: 30%: 1.0%); a blue electron blocking layer 2322 (thickness of 5 nm)/a blue light-emitting layer 2313: a blue host (BH)+a blue dopant (BD) (doping concentration of 3%);

A second hole blocking layer 64: hole blocking (HB) (thickness of 5 nm);

A first electron transporting layer 25: LiQ (liquid Li) (thickness of 35 nm, a ratio of liquid Li to liquid lead is 50%: 50%);

An electron injecting layer 27: an electron injecting layer (EIL) (thickness of 1 nm);

A second electrode 3: Mg and Ag alloy (thickness of 15 nm)+an optical capping layer CPL (capping layer).

Referring to Table 1 and FIG. 7, this example is based on Example 2, the green auxiliary light-emitting layer 2331 is added, the same material as the green light-emitting layer 2312 and a dopant are applied in the green auxiliary light-emitting layer 2331, the green auxiliary light-emitting layer 2331 effectively enlarges a exciton recombination region in the green light-emitting layer 2312, thereby improving the light-emitting stability and further improving the lifespan of the device.

### Example 4

A first electrode 1: metal Ag (thickness of 100 nm)/ITO layer (thickness of 8 nm);

A first hole injecting layer 26/a first hole transporting layer 21: hole transporting (HT): p-type dopant (thickness of 10 nm, doping concentration of 3%)/hole transporting (HT) (B color adjustment);

A first common electron blocking layer 22 (thickness of 5 nm);

A first light-emitting layer 23: a red electron blocking layer 2321/a red light-emitting layer 2311: a red host (RH)+a red dopant (RD) (doping concentration of 3%); a green auxiliary light-emitting layer 2331: a green host (GH)+G-TADF (a ratio of 70%: 30%)/a green light-emitting layer 2312: a green host (GH)+G-TADF+a green dopant (GD) (a ratio of 69%: 30%: 1.0%); a blue electron blocking layer 2322 (thickness of 5 nm)/a blue light-emitting layer 2313: a blue host (BH)+a blue dopant (BD) (doping concentration of 3%);

A first hole blocking layer 24: HB (5 nm);

A charge-generation structure 5: N-type charge-generation layer 51: n-CG: Yb (1%)/P-type charge-generation layer 52: HT: p-type dopant (thickness of 10 nm, doping concentration of 10%);

A second hole transporting layer 61;

A second common electron blocking layer 62 (thickness of 5 nm);

A second light-emitting layer 63: a red electron blocking layer 2321/a red light-emitting layer 2311: a red host (RH)+a red dopant (RD) (doping concentration of 3%); a green auxiliary light-emitting layer 2331: a green host (GH)+G-TADF (a ratio of 80%: 20%)/a green light-emitting layer 2312: a green host (GH)+G-TADF+a green dopant (GD) (a ratio of 69%: 30%: 1.0%); a blue electron blocking layer 2322 (thickness of 5 nm)/a blue light-emitting layer 2313: a blue host (BH)+a blue dopant (BD) (doping concentration of 3%);

A second hole blocking layer 64: hole blocking (HB) (thickness of 5 nm);

A first electron transporting layer 25: LiQ (liquid Li) (thickness of 35 nm, a ratio of liquid Li to liquid lead is 50%: 50%);

An electron injecting layer 27: an electron injecting layer (EIL) (thickness of 1 nm);

A second electrode 3: Mg and Ag alloy (thickness of 15 nm)+an optical capping layer CPL (capping layer).

Referring to Table 1 and FIG. 7, this example was based on Example 3, the efficiency and the lifespan of the device were improved by changing the doping ratio of the auxiliary light-emitting layer 233.

### Example 5

A first electrode 1: metal Ag (thickness of 100 nm)/ITO layer (thickness of 8 nm);

A first hole injecting layer 26/a first hole transporting layer 21: hole transporting (HT): p-type dopant (thickness of 10 nm, doping concentration of 3%)/hole transporting (HT) (B color adjustment);

A first common electron blocking layer 22 (thickness of 5 nm);

A first light-emitting layer 23: a red electron blocking layer 2321/a red light-emitting layer 2311: a red host (RH)+a red dopant (RD) (doping concentration of 3%); a green auxiliary light-emitting layer 2331: a green host (GH)+G-TADF (a ratio of 50%: 50%)/a green light-emitting layer 2312: a green host (GH)+G-TADF+a green dopant (GD) (a ratio of 69%: 30%: 1.0%); a blue electron blocking layer 2322 (thickness of 5 nm)/a blue light-emitting layer 2313: a blue host (BH)+a blue dopant (BD) (doping concentration of 3%);

A first hole blocking layer 24: HB (5 nm);

A charge-generation structure 5: N-type charge-generation layer 51: n-CG: Yb (1%)/P-type charge-generation layer 52: HT: p-type dopant (thickness of 10 nm, doping concentration of 10%);

A second hole transporting layer 61;

A second common electron blocking layer 62 (thickness of 5 nm);

A second light-emitting layer 63: a red electron blocking layer 2321/a red light-emitting layer 2311: a red host (RH)+a red dopant (RD) (doping concentration of 3%); a green auxiliary light-emitting layer 2331: a green host (GH)+G-TADF (a ratio of 80%: 20%)/a green light-emitting layer 2312: a green host (GH)+G-TADF+a green dopant (GD) (a ratio of 69%: 30%: 1.0%); a blue electron blocking layer 2322 (thickness of 5 nm)/a blue light-emitting layer 2313: a blue host (BH)+a blue dopant (BD) (doping concentration of 3%);

A second hole blocking layer 64: hole blocking (HB) (thickness of 5 nm);

A first electron transporting layer 25: LiQ (liquid Li) (thickness of 35 nm, a ratio of liquid Li to liquid lead is 50%: 50%);

An electron injecting layer 27: an electron injecting layer (EIL) (thickness of 1 nm);

A second electrode 3: Mg and Ag alloy (thickness of 15 nm)+an optical capping layer CPL (capping layer).

Referring to Table 1 and FIG. 7, in this example, the doping ratio of the auxiliary light-emitting layer 233 in Example 4 was changed, which improves the device efficiency and the device lifetime.

### Example 6

A first electrode 1: metal Ag (thickness of 100 nm)/ITO layer (thickness of 8 nm);

A first hole injecting layer 26/a first hole transporting layer 21: hole transporting (HT): p-type dopant (thickness of 10 nm, doping concentration of 3%)/hole transporting (HT) (B color adjustment);

A first common electron blocking layer 22 (thickness of 5 nm);

A first light-emitting layer 23: a red electron blocking layer 2321: a first blocking layer 2321a+a second blocking layer 2321b/a red light-emitting layer 2311: a red host (RH)+a red dopant (RD) (doping concentration of 3%); a green light-emitting layer 2312: a green host (GH)+G-TADF+a green dopant (GD) (a ratio of 69%: 30%: 1.0%); a blue electron blocking layer 2322 (thickness of 5 nm)/a blue light-emitting layer 2313: a blue host (BH)+a blue dopant (BD) (doping concentration of 3%);

A first hole blocking layer 24: HB (5 nm);

A charge-generation structure 5: N-type charge-generation layer 51: n-CG: Yb (1%)/P-type charge-generation layer 52: HT: p-type dopant (thickness of 10 nm, doping concentration of 10%);

A second hole transporting layer 61;

A second common electron blocking layer 62 (thickness of 5 nm);

A second light-emitting layer 63: a red electron blocking layer 2321: a first blocking layer 2321a+a second blocking layer 2321b/a red light-emitting layer 2311: a red host (RH)+a red dopant (RD) (doping concentration of 3%); a green light-emitting layer 2312: a green host (GH)+G-TADF+a green dopant (GD) (a ratio of 69%: 30%: 1.0%); a blue electron blocking layer 2322 (thickness of 5 nm)/a blue light-emitting layer 2313: a blue host (BH)+a blue dopant (BD) (doping concentration of 3%);

A second hole blocking layer 64: hole blocking (HB) (thickness of 5 nm);

A first electron transporting layer 25: LiQ (liquid Li) (thickness of 35 nm, a ratio of liquid Li to liquid lead is 50%: 50%);

An electron injecting layer 27: an electron injecting layer (EIL) (thickness of 1 nm);

A second electrode 3: Mg and Ag alloy (thickness of 15 nm)+an optical capping layer CPL (capping layer).

Referring to Table 1 and FIG. 11, this example t is based on Example 2, one red electron blocking layer is additionally added, the red voltage can be effectively increased, the voltage difference between the red light and the blue light can be reduced, the crosstalk problem is improved, the efficiency of the red light device is improved to a certain extent, and the whole power consumption of the red light-emitting device and the blue light-emitting device can be reduced; meanwhile, the number of the chambers and the fine metal masks is unchanged, the process complexity is basically unchanged, and the performance of the green light-emitting device and the blue light-emitting device is basically unchanged.

An embodiment of the present disclosure further provides a display device, including the above display panel.

It should be noted that the display device in this embodiment may be any product or component having a display function, such as electronic paper, a mobile phone, a tablet computer, a television, a notebook computer, a digital photo frame, a navigator, or the like.

It should be noted that in the drawings, the dimensions of the layers and regions may be exaggerated for clarity of the diagram. It may be appreciated that when an element or layer is referred to as being “on” another element or layer, it may be directly on the other element, or an intermediate layer may be present. In addition, it may be appreciated that when an element or layer is referred to as being “under” another element or layer, it may be directly under the other element, or one or more intermediate layers or elements may be present. In addition, it can also be understood that when a layer or element is referred to as being “between” two layers or two elements, it may be the only layer between the two layers or the two elements, or one or more intermediate layers or elements may also be present. Like reference numerals refer to like elements throughout.

In present disclosure, the terms “first” and “second” are used for descriptive purposes only and are not to be construed as indicating or implying relative importance. The term “a plurality of/multiple” refers to two or more unless expressly defined otherwise.

A person skilled in the art will be able to easily conceive of other embodiments of the present disclosure after considering the specification and practice of the present disclosure disclosed herein. The present disclosure is intended to cover any variations, uses or adaptative changes of the present disclosure that follow the general principles of the present disclosure and include common knowledge or customary technical means in the art not disclosed herein. The specification and embodiments are to be regarded as exemplary only, and the actual scope and spirit of the present disclosure are indicated by the appended claims.

It should be understood that the present disclosure is not limited to the specific structures already described above and illustrated in the accompanying drawings, and that various modifications and changes may be made without departing from the scope thereof. The scope of the present disclosure is limited only by the appended claims.

1. A display panel, comprising a light-emitting structure, wherein the light-emitting structure comprises: a first electrode, a first light-emitting unit, and a second electrode;
the first light-emitting unit is disposed at a side of the first electrode, and the second electrode is disposed at a side of the first light-emitting unit away from the first electrode;
the first light-emitting unit comprises a first hole transporting layer, a first electron transporting layer, a first light-emitting layer located between the first hole transporting layer and the first electron transporting layer, and a first common electron blocking layer located between the first hole transporting layer and the first light-emitting layer; and
the first light-emitting layer comprises three sub-light-emitting layers, and at least one of the three sub-light-emitting layers comprises a material having a thermally activated delayed fluorescence characteristic.

2. The display panel according to claim 1, wherein the three sub-light-emitting layers are disposed in a spaced-apart manner and disposed between the first common electron blocking layer and the first electron transporting layer; and
an area of the first common electron blocking layer is greater than or equal to a sum of areas of the three sub-light-emitting layers.

3. The display panel according to claim 2, wherein the first light-emitting layer further comprises one or more sub-electron blocking layers, which have the same quantity as one or more sub-light-emitting layers of the three sub-light-emitting layers that do not include the material having the thermally activated delayed fluorescence characteristic.

4. The display panel according to claim 3, wherein an area of each of the one or more sub-electron blocking layers is greater than or equal to an area of a corresponding one of the one or more sub-light-emitting layers that do not include the material having the thermally activated delayed fluorescence characteristic; and
the one or more sub-electron blocking layers are disposed below the one or more sub-light-emitting layers that do not include the material having the thermally activated delayed fluorescence characteristic in a one-to-one correspondence manner, and are located between the one or more sub-light-emitting layers that do not include the material having the thermally activated delayed fluorescence characteristic and the first common electron blocking layer.

5. The display panel according to claim 3, wherein the first light-emitting layer further comprises one or more auxiliary light-emitting layers, which have a quantity less than or equal to a quantity of the at least one sub-light-emitting layer including the material having the thermally activated delayed fluorescence characteristic, and an area of each of the one or more auxiliary light-emitting layers is greater than or equal to an area of a corresponding one of the at least one sub-light-emitting layer including the material having the thermally activated delayed fluorescence characteristic; and
the one or more auxiliary light-emitting layers are disposed below the at least one sub-light-emitting layer including the material having the thermally activated delayed fluorescence characteristic in a one-to-one correspondence manner, and are located between the at least one sub-light-emitting layer including the material having the thermally activated delayed fluorescence characteristic and the first common electron blocking layer.

6. The display panel according to claim 5, wherein a thickness of each of the one or more auxiliary light-emitting layers is less than a thickness of the corresponding one of the at least one sub-light-emitting layer; each of the one or more auxiliary light-emitting layers comprises a light-emitting host material and a material having a thermally activated delayed fluorescence characteristic, which are the same as those of the corresponding one of the at least one sub-light-emitting layer.

7. The display panel according to claim 5, wherein the three sub-light-emitting layers comprise a red light-emitting layer, a green light-emitting layer, and a blue light-emitting layer, and the green light-emitting layer comprises the material having the thermally activated delayed fluorescence characteristic;
the one or more sub-electron blocking layers comprise a red electron blocking layer and a blue electron blocking layer, the red electron blocking layer and the blue electron blocking layer are disposed below the red light-emitting layer and the blue light-emitting layer, respectively;
the one or more auxiliary light-emitting layers comprise a green auxiliary light-emitting layer; the green auxiliary light-emitting layer is disposed below the green light-emitting layer; and
an energy level value of a first excited triplet state of the first common electron blocking layer is greater than or equal to an energy level value of a first excited triplet state of the material having the thermally activated delayed fluorescence characteristic included in the green light-emitting layer.

8. The display panel according to claim 7, wherein the first common electron blocking layer is made of a hole-type carbazole or aromatic amine-based derivative, and a thickness of the first common electron blocking layer is less than or equal to 10 nm.

9. The display panel according to claim 7, wherein a value of a highest occupied molecular orbital of the blue electron blocking layer is greater than a value of a highest occupied molecular orbital of the blue light-emitting layer, and is less than a value of a highest occupied molecular orbital of the first hole transporting layer; and
a value of a first excited singlet state of the blue electron blocking layer is greater than a value of a first excited singlet state of the blue light-emitting layer.

10. The display panel according to claim 7, wherein each of an absolute value of a difference between a value of a highest occupied molecular orbital of the first common electron blocking layer and a value of a highest occupied molecular orbital of the first hole transporting layer, an absolute value of a difference between the value of the highest occupied molecular orbital of the first common electron blocking layer and a value of a highest occupied molecular orbital of the blue electron blocking layer, and an absolute value of a difference between the value of the highest occupied molecular orbital of the first common electron blocking layer and a value of a highest occupied molecular orbital of the red electron blocking layer is less than or equal to 0.25 eV.

11. The display panel according to claim 1, wherein the light-emitting structure further comprises a first hole blocking layer, and the first hole blocking layer is disposed at a side of the first light-emitting layer away from the first electrode and located between the first light-emitting layer and the first electron transporting layer.

12. The display panel according to claim 1, wherein the light-emitting structure further comprises a charge-generation structure and a second light-emitting unit;
the charge-generation structure is disposed at a side of the first light-emitting unit away from the first electrode; and
the second light-emitting unit is disposed at a side of the charge-generation structure away from the first electrode.

13. The display panel according to claim 12, wherein the second light-emitting unit comprises a second hole transporting layer, a second light-emitting layer between the second hole transporting layer and the first electron transporting layer, and a second common electron blocking layer between the second hole transporting layer and the second light-emitting layer; and
the second light-emitting layer comprises three sub-light-emitting layers, and at least one of the three sub-light-emitting layers comprises a material having a thermally activated delayed fluorescence characteristic.

14. The display panel according to claim 12, wherein the charge-generation structure comprises an N-type charge-generation layer and a P-type charge-generation layer;
the N-type charge-generation layer is disposed at a side of the first light-emitting unit away from the first electrode; and
the P-type charge-generation layer is disposed at a side of the N-type charge-generation layer away from the first electrode.

15. The display panel according to claim 12, wherein the light-emitting structure further comprises a hole injecting layer and an electron injecting layer;
the first electrode is an anode, and the second electrode is a cathode;
the hole injecting layer is disposed between the first hole transporting layer and the first electrode; and
the electron injecting layer is disposed between the first electron transporting layer and the second electrode.

16. A display device, comprising the display panel according to claim 1.

17. The display panel according to claim 7, wherein an absolute value of a difference between a value of a highest occupied molecular orbital of the first common electron blocking layer and a value of a highest occupied molecular orbital of the red electron blocking layer is greater than or equal to a difference between the value of the highest occupied molecular orbital of the first common electron blocking layer and a value of a highest occupied molecular orbital of the blue electron blocking layer.

18. The display panel according to claim 5, wherein the three sub-light-emitting layers comprise a red light-emitting layer, a green light-emitting layer, and a blue light-emitting layer, and the green light-emitting layer comprises the material having the thermally activated delayed fluorescence characteristic; and
the one or more sub-electron blocking layers comprise two red electron blocking layers that are stacked below the red light-emitting layer and a blue electron blocking layer disposed below the blue light-emitting layer.

19. The display panel according to claim 15, wherein the light-emitting structure further comprises a second hole blocking layer, and the second hole blocking layer is disposed between the second light-emitting layer and the first electron transporting layer.

20. The display panel according to claim 12, wherein a structure of the second light-emitting unit is the same as that of the first light-emitting unit.
